(19) United States
(12) Patent Application Publication
(10) Pub. No.: US 2023/0290874 A1
(43) Pub. Date: Sep. 14, 2023

(54) METHOD OF MANUFACTURING SILICON CARBIDE SEMICONDUCTOR DEVICE, SILICON CARBIDE SEMICONDUCTOR DEVICE, AND POWER CONVERSION APPARATUS

(71) Applicant: Mitsubishi Electric Corporation, Tokyo (JP)

(72) Inventors: Motoru YOSHIDA, Tokyo (JP); Rina TANAKA, Tokyo (JP); Yutaka FUKUI, Tokyo (JP); Hideyuki HATTA, Tokyo (JP)

(73) Assignee: Mitsubishi Electric Corporation, Tokyo (JP)

(21) Appl. No.: 18/019,824

(22) PCT Filed: Sep. 30, 2020
(86) PCT No.: PCT/JP2020/037178

§ 371 Date: Feb. 6, 2023

(51) Int. Cl. H01L 29/78; H01L 29/66

(52) U.S. Cl. CPC H01L 29/7806; H01L 29/6606; H01L 29/66068; H01L 29/7813

(57) ABSTRACT

A method of manufacturing a silicon carbide semiconductor device includes a step of forming gate trench, a step of forming Schottky trench, a step of forming a silicon oxide film in the gate trench and the Schottky trench, a step of forming a polycrystalline silicon film inside the silicon oxide film, a step of etching back the polycrystalline silicon film, a step of forming an interlayer insulating film on a gate electrode in the gate trench, a step of removing, by wet etching, the polycrystalline silicon film in the Schottky trench after opening a hole in the interlayer insulating film, a step of forming an ohmic electrode on a source region, a step of removing the silicon oxide film in the Schottky trench, and a step of forming a source electrode in the Schottky trench, which is in Schottky junction with a drift layer.

### TECHNICAL FIELD

The present disclosure relates to a method of manufacturing a silicon carbide semiconductor device having trench gates and a method of manufacturing a power conversion apparatus including the silicon carbide semiconductor device.

### BACKGROUND ART

A power semiconductor device in which unipolar switching elements such as MOSFETs (Metal-Oxide-Semiconductor Field-Effect-Transistor) and unipolar freewheeling diodes such as Schottky Barrier Diode (SBD) are built-in, has been known. Such a semiconductor device can be realized by arranging MOSFET cells and SBD cells in parallel on the same chip, and typically be realized by providing a Schottky electrode in a specific region within the chip and operating that region as an SBD.

By having the freewheeling diode built-in in the chip of the switching element, the cost can be reduced compared to the case where the freewheeling diode is externally attached to the switching element. In particular, in a MOSFET using silicon carbide (SiC) as a base material, suppression of bipolar operation due to the parasitic pn diode by having the SBD built-in thereof is one of the benefits. This is because, in a silicon carbide semiconductor device, the reliability of the device may be impaired due to the expansion of crystal defects caused by recombination energy of carriers due to parasitic pn diode operation.

Also, in comparison with a planar type MOSFET having a structure in which the gate electrode is formed on the surface of the semiconductor layer, in a trench gate type MOSFET having a structure in which a gate electrode is embedded in a trench formed in a semiconductor layer, a channel can be formed on the sidewall of the trench, which improves the channel width density, reducing the on-resistance.

When manufacturing such a trench type MOSFET with built-in SBD, a Schottky trench in which the Schottky electrode is embedded and a gate trench in which the gate electrode is embedded are formed by an etching method, a gate insulating film and a gate electrode are formed in the gate trench, an interlayer insulating film is formed thereon, a contact hole is formed in the interlayer insulating film, and, concurrently, an Ni film is deposited and heat-treated to form a silicide layer, while leaving part of the interlayer insulating film on the sidewall of the Schottky trench (for example, Patent Document 1).

### PRIOR ART DOCUMENTS

### Patent Document(s)

[Patent Document 1] Japanese Patent Application Laid-Open No. 2018-182235 (FIG. 6, etc.)

### SUMMARY

### Problem to Be Solved by the Invention

Accordingly, in the case in which the Schottky trench is formed and then, polycrystalline silicon, which is to be the gate electrode, is formed in the gate trench, and silicide such as metal silicide is formed on the source region in the state where the Schottky trench is filled with the interlayer insulating film, polycrystalline silicon and Ni remain in the holes (cavities, cracks) formed in the interlayer insulating film filled in the Schottky trench, polycrystalline silicon, metal and its silicide remain where they should not exist, and they are released as foreign matters when the interlayer insulating film is removed, causing contamination in some cases.

Also, when forming a gate insulating film of silicon oxide and a gate electrode of polycrystalline silicon in a gate trench, the polycrystalline silicon is processed by a dry etching method in many cases, when silicon oxide and polycrystalline silicon are also once formed in the Schottky trench in the same manner as the gate trench, and the polycrystalline silicon in the Schottky trench is removed by dry etching, part of the polycrystalline silicon may remain on the gate insulating film at the bottom of the Schottky trench, if silicidation is performed by depositing and heating a metal layer in this state, silicide may be formed also at the bottom of the Schottky trench, the silicide is released in a later step, causing contamination in some cases.

The present disclosure has been made to solve the above-described problems, and an object thereof is to provide a method of manufacturing a silicon carbide semiconductor device in which polycrystalline silicon material or metal silicide material remaining in unintended parts is prevented with little defective or high reliability.

### Means to Solve the Problem

According to the present disclosure, a method of manufacturing a silicon carbide semiconductor device includes a step of forming a drift layer of a first conductive type on a silicon carbide semiconductor substrate, a step of forming a well region of a second conductive type on the drift layer, forming a source region of the first conductive type in an upper layer portion of the well region, a step of forming a gate trench extending through the source region and the well region and reaching the drift layer, a step of forming a Schottky trench provided apart from the gate trench and reaching the drift layer, a step of forming a silicon oxide film in contact with the inner walls of the gate trench and the Schottky trench, a step of forming a polycrystalline silicon film inside the silicon oxide film in the gate trench and the Schottky trench, a step of forming a gate electrode in the gate trench by removing the polycrystalline silicon film outside the gate trench and the Schottky trench by etching back the polycrystalline silicon film, a step of forming an interlayer insulating film on the gate electrode in the gate trench, a step of removing, by wet etching, the polycrystalline silicon film in the Schottky trench after opening a hole in the interlayer insulating film, after the step of removing the polycrystalline silicon film in the Schottky trench, a step of forming an ohmic electrode on the source region, after the step of forming the ohmic electrode, a step of removing the silicon oxide film inside the Schottky trench, and after the step of removing the silicon oxide film in the Schottky trench, a step of forming a source electrode to be in a Schottky junction with the drift layer in the Schottky trench.

### Effects of the Invention

According to the present disclosure, the method of manufacturing the silicon carbide semiconductor device ensures to manufacture the silicon carbide semiconductor device with little defective or high reliability.

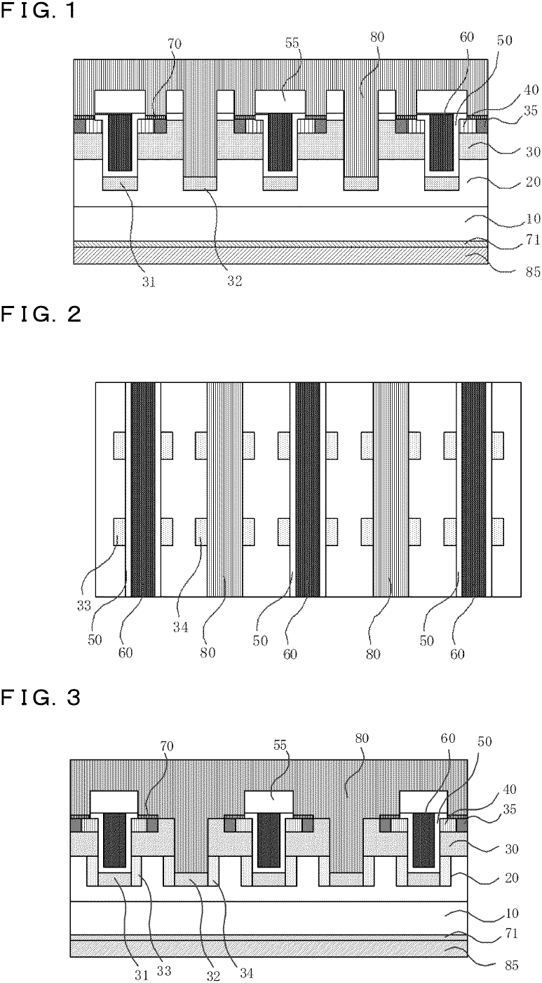

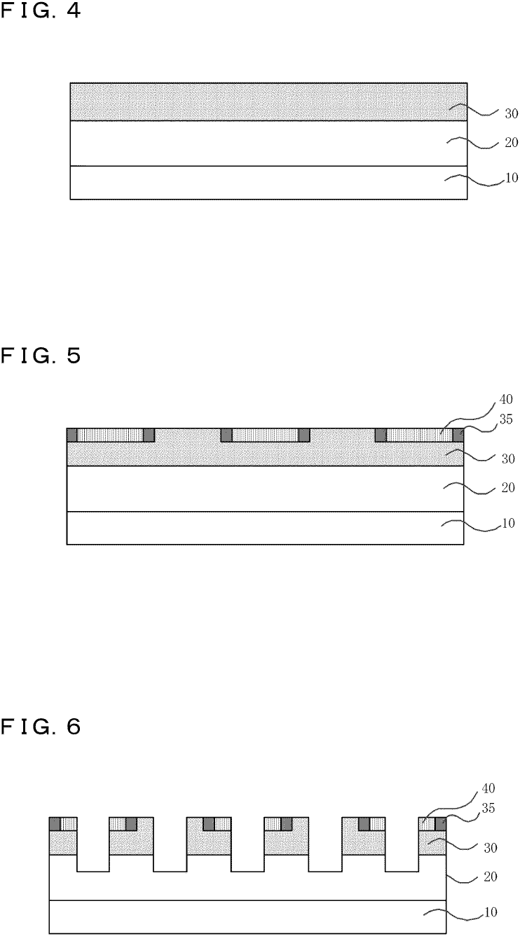

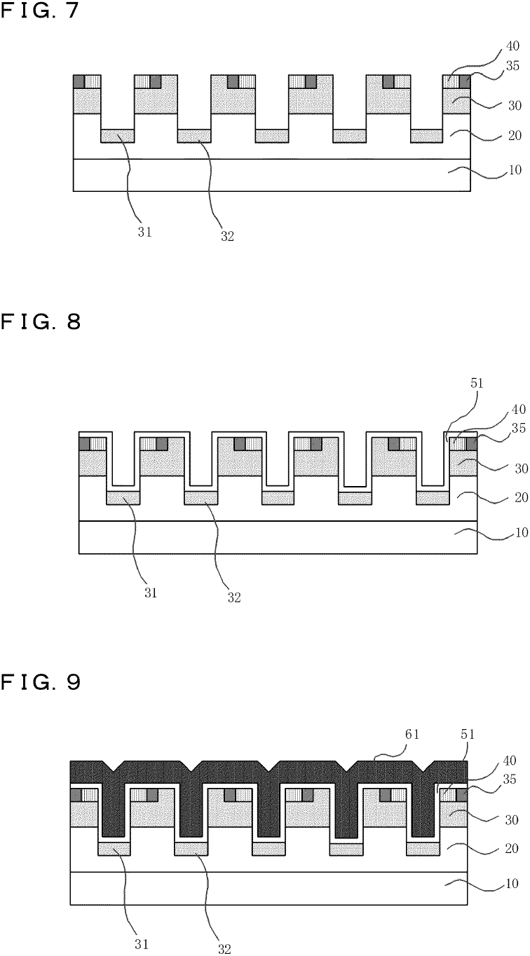

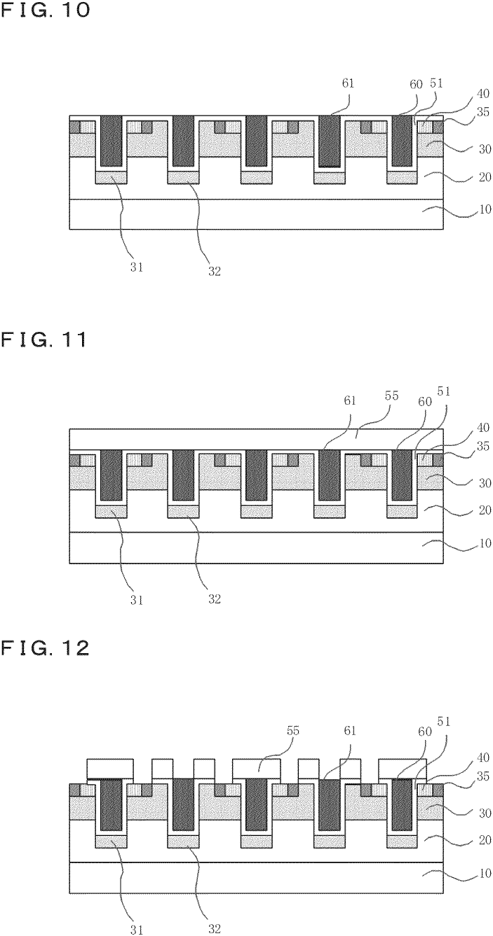

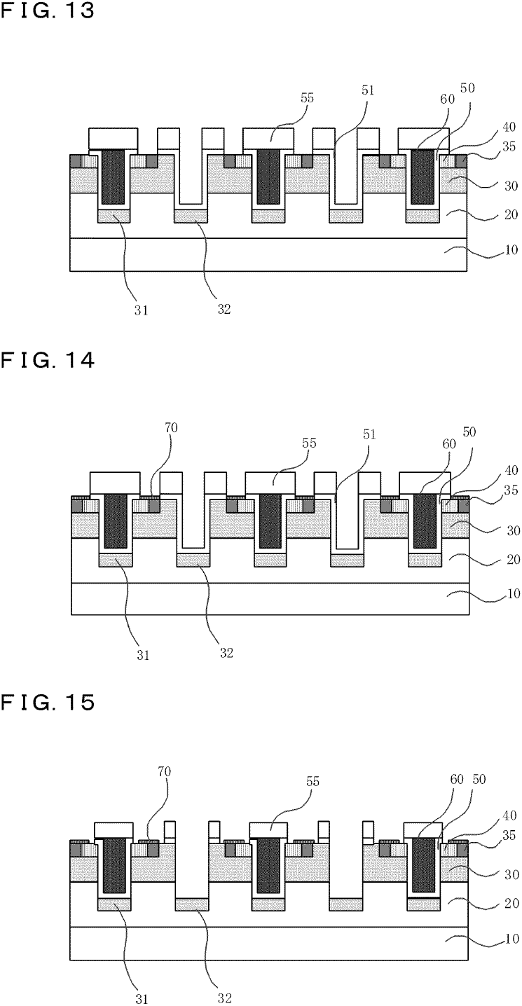

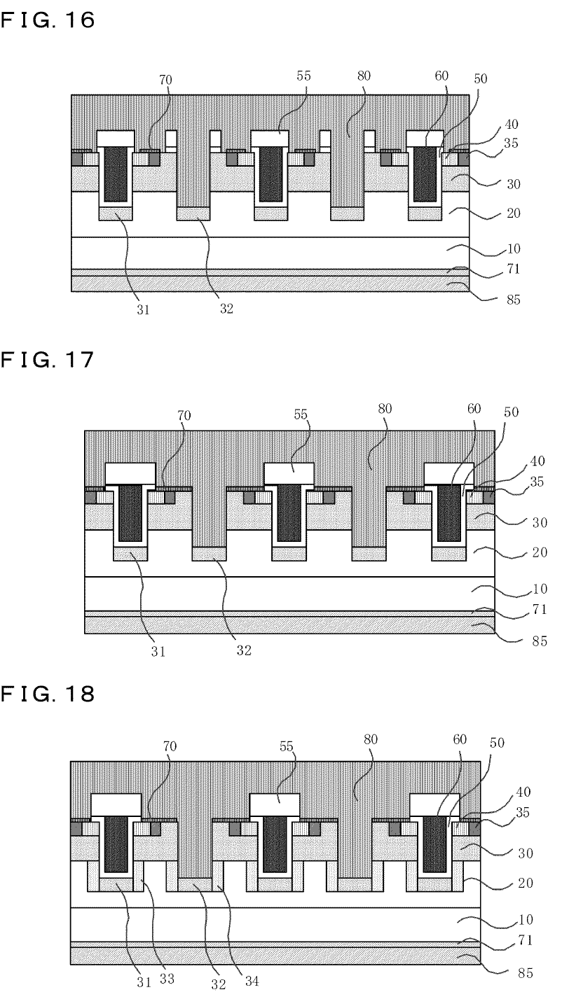

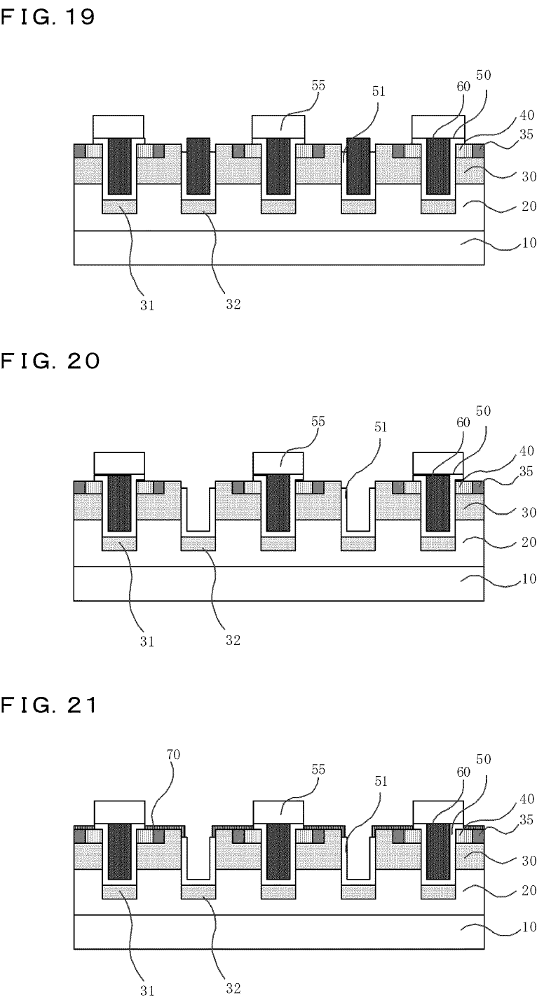

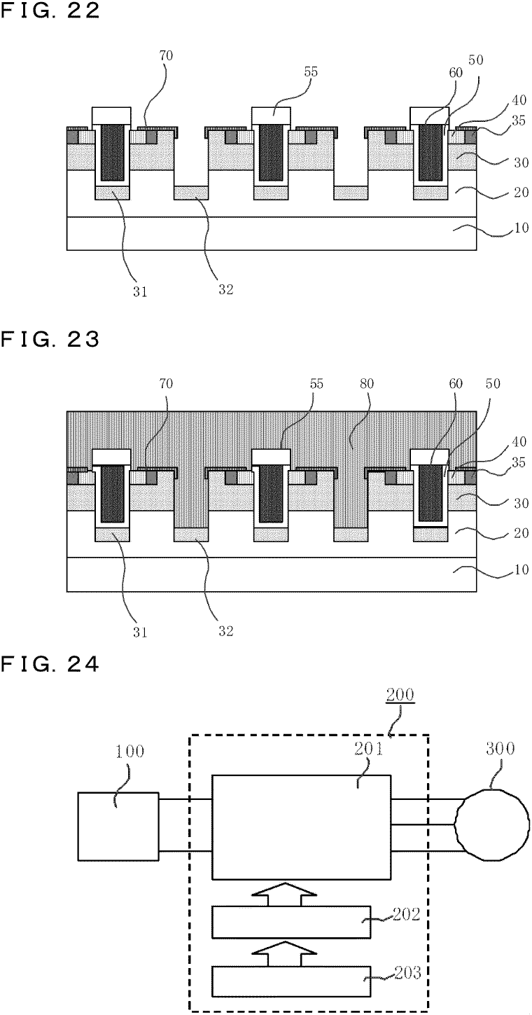

### BRIEF DESCRIPTION OF DRAWINGS

[FIG. 1] A cross-sectional view of a silicon carbide semiconductor device manufactured by a method of manufacturing the silicon carbide semiconductor device according to a first embodiment.

[FIG. 2] A plan view of the silicon carbide semiconductor device manufactured by the method of manufacturing the silicon carbide semiconductor device according to the first embodiment.

[FIG. 3] A cross-sectional view of the silicon carbide semiconductor device manufactured by the method of manufacturing the silicon carbide semiconductor device according to the first embodiment.

[FIG. 4] A cross-sectional view for explaining the method of manufacturing the silicon carbide semiconductor device according to the first embodiment.

[FIG. 5] A cross-sectional view for explaining the method of manufacturing the silicon carbide semiconductor device according to the first embodiment.

[FIG. 6] A cross-sectional view for explaining the method of manufacturing the silicon carbide semiconductor device according to the first embodiment.

[FIG. 7] A cross-sectional view for explaining the method of manufacturing the silicon carbide semiconductor device according to the first embodiment.

[FIG. 8] A cross-sectional view for explaining the method of manufacturing the silicon carbide semiconductor device according to the first embodiment.

[FIG. 9] A cross-sectional view for explaining the method of manufacturing the silicon carbide semiconductor device according to the first embodiment.

[FIG. 10] A cross-sectional view for explaining a method of manufacturing when the method of manufacturing the silicon carbide semiconductor device according to the first embodiment is not adopted.

[FIG. 11] A cross-sectional view for explaining the method of manufacturing when the method of manufacturing the silicon carbide semiconductor device according to the first embodiment is not adopted.

[FIG. 12] A cross-sectional view for explaining the method of manufacturing when the method of manufacturing the silicon carbide semiconductor device according to the first embodiment is not adopted.

[FIG. 13] A cross-sectional view for explaining the method of manufacturing when the method of manufacturing the silicon carbide semiconductor device according to the first embodiment is not adopted.

[FIG. 14] A cross-sectional view of the silicon carbide semiconductor device manufactured by the method of manufacturing the silicon carbide semiconductor device according to the first embodiment.

[FIG. 15] A plan view of the silicon carbide semiconductor device manufactured by the method of manufacturing the silicon carbide semiconductor device according to the first embodiment.

[FIG. 16] A cross-sectional view of the silicon carbide semiconductor device according to the first embodiment.

[FIG. 17] A cross-sectional view of a silicon carbide semiconductor device according to a second embodiment.

[FIG. 18] A cross-sectional view of the silicon carbide semiconductor device according to the second embodiment.

[FIG. 19] A cross-sectional view for explaining a method of manufacturing the silicon carbide semiconductor device according to the second embodiment.

[FIG. 20] A cross-sectional view for explaining the method of manufacturing the silicon carbide semiconductor device according to the second embodiment.

[FIG. 21] A cross-sectional view for explaining the method of manufacturing the silicon carbide semiconductor device according to the second embodiment.

[FIG. 22] A cross-sectional view for explaining the method of manufacturing the silicon carbide semiconductor device according to the second embodiment.

[FIG. 23] A cross-sectional view of the silicon carbide semiconductor device according to the second embodiment.

[FIG. 24] A schematic drawing illustrating a configuration of a power conversion apparatus manufactured by a method of manufacturing the power conversion apparatus according to a third embodiment.

### DESCRIPTION OF EMBODIMENT(S)

Hereinafter, embodiments will be described with reference to the attached drawings. It should be noted that the drawings are illustrated schematically, and the mutual relationship between the sizes and positions of the images illustrated in different drawings is not necessarily accurately illustrated and may be changed as appropriate. In addition, in the following description, the same components are denoted and illustrated by the same reference numerals, and the names and functions thereof are also similar. Accordingly, detailed descriptions thereof may be omitted.

### First Embodiment

First, the structure of a silicon carbide semiconductor device manufactured by a method of manufacturing according to a first embodiment of the present disclosure will be described.

FIG. 1 is a cross-sectional view of a part of an active region of a trench type silicon carbide MOSFET with built-in Schottky barrier diode (SiC trench MOSFET with built-in SBD), which is a silicon carbide semiconductor device manufactured by the method of manufacturing according to the first embodiment. FIG. 2 is a plan view of the SiC trench MOSFET with built-in SBD illustrated in FIG. 1, and is a plan view at a certain depth where trenches are formed.

In FIG. 1, a drift layer 20 composed of n-type silicon carbide is formed on the front surface of a semiconductor substrate 10 composed of n-type low-resistance silicon carbide. A well region 30 composed of p-type silicon carbide is provided in the surface layer portion of the drift layer 20. Source regions 40 composed of n-type silicon carbide are formed in the upper layer portion of the well region 30. Contact regions 35 composed of low-resistance p-type silicon carbide are formed in the surface layer portion of the well region 30 adjacent to the source regions 40. Here, regardless of the presence or absence of ion implantation, the region made of silicon carbide (the region formed as drift layer 20) is called a silicon carbide layer.

Gate trenches extending through the source regions 40 and the well region 30 and reaching the drift layer 20 are formed at portions in the well region 30 where the source regions 40 are formed. Schottky trenches extending through the well region 30 and reaching the drift layer 20 are formed at portions each apart from the gate trenches in the well region 30 where the source regions 40 are not formed.

Inside the gate trench, a gate electrode 60 composed of low-resistance polycrystalline silicon is formed via a gate insulating film 50. A first protection region 31 of p-type is formed in the drift layer 20 at the bottom of the gate trench. A second protection region 32 of p-type is formed in the drift layer 20 at the bottom of the Schottky trench.

An interlayer insulating film 55 is formed on the gate electrodes 60 and the gate insulating film 50 in the gate trenches and in the vicinity of the openings of the Schottky trenches. Ohmic electrodes 70 composed of metal silicide are formed on the source regions 40 and the contact regions 35. A source electrode 80 is formed inside the Schottky trenches, on the ohmic electrodes 70, and on the interlayer insulating film 55, and the source electrode 80 inside the Schottky trench and the drift layer 20 are in Schottky junction. A rear surface ohmic electrode 71 and a drain electrode 85 are formed on the surface of the semiconductor substrate 10 opposite to the drift layer 20 where the drift layer 20 is not formed.

At a position where the source electrode 80 is in contact with the drift layer 20 in the Schottky trench, the source electrode 80 is composed of any materials of Ti, Mo, W, and Ni.

As illustrated in the plan view of FIG. 2, the gate trenches in which the gate electrodes 60 are formed and the Schottky trenches in which the source electrode 80 is formed are linearly formed in a certain direction and they are arranged in an alternate manner. The distance between the gate trench and the Schottky trench is constant. Here, in the gate trench, first connection regions 33 of p-type are formed from the gate trench toward the drift layer 20 in a direction orthogonal to the extending direction of the gate trench, and in the Schottky trench, second connection regions 34 are formed from the Schottky trench toward the drift layer 20 in a direction orthogonal to the extending direction of the Schottky trench.

FIG. 3 is a cross-sectional view of the SiC trench MOSFET with built-in SBD manufactured by the method of manufacturing according to the first embodiment at the position where the first connection regions 33 and the second connection regions 34 are formed. As illustrated in FIG. 3, the first connection region 33 connects the first protection region 31 and the well region 30. Also, the second connection region 34 connects the second protection region 32 and the well region 30. A plurality of first connection regions 33 and a plurality of second connection regions 34 are formed at predetermined intervals along the direction in which the gate trenches and the Schottky trenches extend, respectively.

Hereafter, the method of manufacturing a SiC-MOSFET with built-in SBD being a silicon carbide semiconductor device according to the first embodiment of the present disclosure, will be described with reference to cross-sectional views of FIGS. 4 to 16 corresponding to the cross-section illustrated in FIG. 1.

On the semiconductor substrate 10 composed of n-type low-resistance silicon carbide having a (0001) plane orientation of the first main surface with an off angle and a 4H polytype, the drift layer 20 composed of silicon carbide is epitaxially grown with an impurity concentration of 1×10¹⁵ cm⁻³ or more and 1×10¹⁷ cm⁻³ or less and a thickness of 5 µm or more and 50 µm or less by chemical vapor deposition (CVD method).

Subsequently, Al (aluminum), which is a p-type impurity, is ion-implanted into the front surface of the drift layer 20. At this point, the depth of ion implantation of Al is about 0.5 to 3 µm, which does not exceed the thickness of the drift layer 20. The impurity concentration of ion-implanted Al is in the range of 1×10¹⁷ cm⁻³ or more and 1×10¹⁹ cm⁻³ or less, which is higher than the impurity concentration of the drift layer 20. The region implanted with Al ions in the step becomes the well region 30, and the structure illustrated in the cross section in FIG. 4 is obtained.

Next, an implantation mask is formed with a photoresist or the like so that predetermined portions of the well region 30 on the front surface of the drift layer 20 are opened, and N (nitrogen), which is an n-type impurity, is ion-implanted. The ion implantation depth of N is assumed to be shallower than the thickness of the well region 30. The impurity concentration of ion-implanted N is in the range of 1×10¹⁸ cm⁻³ or more and 1×10²¹ cm⁻³ or less and exceeds the p-type impurity concentration of the well region 30. Of the regions into which N is implanted in the step, the regions exhibiting the n-type become the source regions 40. After this, the implantation mask is removed.

Further, with the same method, into predetermined regions of the well region 30 adjacent to the source regions 40, Al is ion-implanted with an impurity concentration in the range of 1×10¹⁹ cm⁻³ or more and 1×10²¹ cm⁻³ or less, which is higher than the impurity concentration of the well region 30, thereby forming the contact regions 35. Up until this step, the structure of the cross-sectional view illustrated in FIG. 5 is obtained.

Next, a resist mask is formed to partially open regions where the source regions 40 are formed, and the gate trenches each of which extends through the source region 40 and the well region 30 and reaches the drift layer 20 are formed by dry etching. Similarly, a resist mask is formed to partially open regions where the source regions 40 are not formed, and the Schottky trenches each of which extends through the well region 30 and reaches the drift layer 20 are formed by dry etching.

The gate trenches and the Schottky trenches may be formed with the same depth in the same dry etching process. Up until this step, the structure of the cross-sectional view illustrated in FIG. 6 is obtained.

Subsequently, as illustrated in the schematic cross-sectional view of FIG. 7, p-type impurities are ion-implanted into the drift layer 20 at the bottom of the gate trenches and the Schottky trenches to form the first protection regions 31 and the second protection regions 32, respectively. After the ions are implanted, the resist mask is removed. Further, a resist mask is formed with openings for forming the first connection regions 33 and the second connection regions 34, and p-type impurities are obliquely ion-implanted to form the first connection regions 33 and the second connection regions 34. After the ions are implanted, the resist mask is removed.

Next, annealing is performed in an inert gas atmosphere such as argon (Ar) gas at a temperature of 1300 to 1900° C. for 30 seconds to 1 hour using a heat treatment apparatus. The annealing electrically activates the ion-implanted N and Al.

Subsequently, the silicon carbide layer front surface including inside the gate trenches and the Schottky trenches is thermally oxidized to form a silicon oxide film 51 having a thickness of 10 nm or more and 300 nm or less. The silicon oxide film 51 is formed in contact with the inner walls of the gate trenches and the Schottky trenches. The silicon oxide film 51 may be formed by the CVD method. Up until this step, the structure of the cross-sectional view illustrated in FIG. 8 is obtained.

Next, a polycrystalline silicon film 61 having conductivity and a thickness of 300 nm or more and 2000 nm or less is formed on the silicon oxide film 51 by the low-pressure CVD method, thereby forming the one in the cross-sectional view illustrated in FIG. 9. Subsequently, by etching back, the polycrystalline silicon film 61 is left only inside the gate trenches and inside the Schottky trenches, resulting in the structure illustrated in the cross-sectional view of FIG. 10. The polycrystalline silicon film 61 in the gate trenches becomes the gate electrodes 60.

Subsequently, as illustrated in a schematic cross-sectional view of FIG. 11, an interlayer insulating film 55 composed of silicon oxide and having a thickness of 500 nm or more and 3000 nm or less is formed by the low-pressure CVD method.

Next, the interlayer insulating film 55 and the silicon oxide film 51 are patterned so as to open above the regions where the source regions 40 and the contact regions 35 are formed and above the Schottky trenches to form the cross-sectional structure illustrated in FIG. 12.

Subsequently, as illustrated in the cross-sectional view of FIG. 13, the polycrystalline silicon film 61 in the Schottky trenches is removed by wet etching using an alkaline etchant such as an alkaline developer.

Next, ohmic electrodes 70 composed of silicide are formed on the source regions 40 and the contact regions 35, as illustrated in the cross-sectional view of FIG. 14, by depositing and annealing a metal such as Ni.

Subsequently, as illustrated in the cross-sectional view of FIG. 15, the silicon oxide film 51 in the Schottky trenches and parts (surface) of the interlayer insulating film 55 are removed by wet etching using hydrofluoric acid or the like. At this point, the natural oxide film on the front surface of the ohmic electrodes 70 can also be removed at the same time. The silicon oxide film 51 remaining in the gate trenches becomes the gate insulating film 50.

Next, a source electrode 80 to be in a Schottky junction with the drift layer 20 is formed inside the Schottky trenches and on the ohmic electrodes 70 of the gate trenches, and by forming the back surface ohmic electrode 71 and the drain electrode 85 on the rear surface side, the SiC-MOSFET with built-in SBD whose cross section is illustrated in FIG. 2 is manufactured.

As in one of the conventional methods, when forming a contact hole in the interlayer insulating film 55 that leads to the ohmic electrodes 70 with the Schottky trenches filled with the interlayer insulating film 55, it was necessary to form a contact hole while covering the Schottky trenches with a resist mask, and then form another resist mask to remove the interlayer insulating film 55 in the Schottky trenches. However, manufacturing the SiC-MOSFET with built-in SBD by the method of manufacturing of the present embodiment allows manufacturing the SiC-MOSFET with built-in SBD with the number of times of forming resist masks reduced, reducing the manufacturing cost.

When the SiC-MOSFET with built-in SBD is manufactured by the method of manufacturing of the present embodiment, the silicon oxide film 51 and parts (surface) of the interlayer insulating film 55 are wet-etched when the silicon oxide film 51 in the inside the Schottky trenches is wet-etched; therefore, portions have emerged where the source electrode 80 and the source region 40 or the contact region 35 are in direct contact with each other on the gate trench side around the ohmic electrode 70, as illustrated in the cross-sectional view of FIG. 16.

According to the method of manufacturing the silicon carbide semiconductor device of the present embodiment, remaining of the silicide and the gate insulating film in the Schottky trenches is prevented, and adding foreign matter, which causes contamination during steps, is also prevented; therefore, a silicon carbide semiconductor device with few defects can be manufactured.

### Second Embodiment

First, the structure of a silicon carbide semiconductor device manufactured by a method of manufacturing according to a second embodiment of the present disclosure will be described.

FIG. 17 is a cross-sectional schematic view of a unit cell of an active region of a trench type silicon carbide MOSFET with built-in Schottky barrier diode (SiC-MOSFET with built-in SBD), which is a silicon carbide semiconductor device manufactured by the method of manufacturing according to the second embodiment. FIG. 18 is a cross-sectional view of the position where the first connection regions 33 and the second connection regions 34 of the SiC-MOSFET with built-in SBD are formed. A plan view illustrating the depth of the trenches is the same as FIG. 2 of the first embodiment.

In the first embodiment, the ohmic electrodes 70 of the MOSFET in the gate trenches have been formed in the holes formed in the positions separated from the holes in the interlayer insulating film 55 in the upper parts of the Schottky trenches in the cross-sectional view. However, in a method of manufacturing a silicon carbide semiconductor device according to the present embodiment, the ohmic electrodes 70 of the MOSFET in the gate trenches and the source electrode 80 inside the Schottky trenches are formed in the same hole of the interlayer insulating film 55, that is, the interlayer insulating film 55 is not provided between the ohmic electrodes 70 and the Schottky trenches 55 which are adjacent to each other. The other respects are the same as those of the first embodiment; therefore, detailed description thereof will be omitted.

In FIG. 17, a drift layer 20 is formed on the front surface of a semiconductor substrate 10. A well region 30 is provided in the surface layer portion of the drift layer 20, and source regions 40 and contact regions 35 are formed in the upper layer portion of the well region 30. Gate trenches extending through the source regions 40 and the well region 30 and reaching the drift layer 20 are formed at portions in the well region 30 where the source regions 40 are formed. Schottky trenches extending through the well region 30 and reaching the drift layer 20 are formed at portions in the well region 30 where the source regions 40 are not formed.

The gate insulating film 50 is formed the inside the gate trench, and the gate electrode 60 is formed inside thereof. A first protection region 31 of p-type is formed in the drift layer 20 at the bottom of the gate trench. A second protection region 32 is formed in the drift layer 20 at the bottom of the Schottky trench.

An interlayer insulating film 55 is formed on the gate electrodes 60 and the gate insulating film 50 in the gate trenches. Ohmic electrodes 70 are formed on the source regions 40, the contact regions 35, and the well regions 30 in the vicinity of the Schottky trenches. No interlayer insulating film 55 is formed between the ohmic electrodes 70 and the Schottky trenches which are adjacent to each other. Source electrode 80 is formed inside the Schottky trenches, on the ohmic electrodes 70, and on the interlayer insulating film 55, and the source electrode 80 inside the Schottky trench and the drift layer 20 are in Schottky junction. A rear surface ohmic electrode 71 and a drain electrode 85 are formed on the surface of the semiconductor substrate 10 opposite to the drift layer 20 where the drift layer 20 is not formed.

Further, in FIG. 18, which is a cross-sectional view of the position where the first protection regions 31 and the second protection regions are formed, in addition to the configuration of FIG. 17, the first protection region 31 is formed in the drift layer 20 on the wall portion of the gate trench, and the second protection region 32 is formed in the drift layer 20 on the wall portion of the Schottky trench.

Hereafter, the method of manufacturing a SiC-MOSFET with built-in SBD being a silicon carbide semiconductor device according to the second embodiment of the present disclosure, will be described with reference to cross-sectional views of FIGS. 19 to 23 corresponding to the cross-section illustrated in FIG. 17.

In the method of manufacturing the silicon carbide semiconductor device of the present embodiment, the Steps from FIG. 4 to FIG. 11 of the first embodiment are the same as those of the first embodiment. As illustrated in the cross-sectional view of FIG. 19, after the structure of FIG. 11 is formed, the interlayer insulating film 55 and the silicon oxide film 51 are etched except for the above portions of the gate electrodes 60 and the silicon oxide film 51 in the gate trenches. Etching to be performed may be plasma etching, or may be the combining of plasma etching and wet etching. At this point, the polycrystalline silicon film 61 in the Schottky trenches is basically not etched, and the upper parts of the silicon oxide film composed of the same material as the gate insulating film 50 in the Schottky trenches is etched. The silicon oxide film 51 remains in the lower parts in the Schottky trenches.

Subsequently, as illustrated in the cross-sectional view of FIG. 20, the polycrystalline silicon film 61 in the Schottky trenches is selectively etched by wet etching.

Next, through steps such as depositing and annealing the metal that composing the ohmic electrode 70, as illustrated in the cross-sectional view of FIG. 21, the ohmic electrodes 70 composed of silicide are formed on the source regions 40, on the contact regions 35, on the well regions 30 in the vicinity of the Schottky trenches, and in portions of the well regions 30 in the vicinity of the upper end of the Schottky trenches.

Subsequently, as illustrated in the cross-sectional view of FIG. 22, the silicon oxide film 51 in the Schottky trenches is wet-etched with hydrofluoric acid or the like.

Next, a source electrode 80 to be in a Schottky junction with the drift layer 20 is formed on the interlayer insulating film 55 and the inside the Schottky trenches and on the ohmic electrodes 70 of the gate trenches, and by forming the back surface ohmic electrode 71 and the drain electrode 85 on the rear surface side, the SiC-MOSFET with built-in SBD whose cross section is illustrated in FIG. 17 is manufactured.

Here, in some cases, the ohmic electrode 70 is formed from the outside of the opening of the Schottky trench to a part of the inside the Schottky trench, and as illustrated in the cross-sectional view of FIG. 23, an ohmic electrode 70 may also be formed on the upper portion of the inside the Schottky trench.

Further, the silicon oxide film 51 and parts (surface) of the interlayer insulating film 55 are wet-etched when the silicon oxide film 51 in inside the Schottky trenches is wet-etched; therefore, portions have emerged where the source electrode 80 and the source region 40 or the contact region 35 are in direct contact with each other on the gate trench side around the ohmic electrode 70, as illustrated in the cross-sectional view of FIG. 22.

According the method of manufacturing a SiC-MOSFET with built-in SBD being the silicon carbide semiconductor device according to the present embodiment, remaining of the silicide and the gate insulating film in the Schottky trenches is prevented, and adding foreign matter, which causes contamination during steps, is also prevented; therefore, a silicon carbide semiconductor device with few defects can be manufactured.

Further, according to the silicon carbide semiconductor device of the present embodiment, forming the interlayer insulating film 55 in the vicinity of the Schottky trench is not required and there is no need to secure a space for forming the interlayer insulating film 55, the distance between the trenches can be made smaller; therefore, the silicon carbide semiconductor device with a higher current density can be manufactured.

Although the method of forming the well regions 30 and the source regions 40 by ion implantation has been described in the first and second embodiments, the well regions 30 and the source regions 40 may be formed by another method, for example, they are formed by an epitaxial method. Moreover, although the example in which the well regions 30 are formed over the entire surface has been described, the well regions 30 may be formed in part of the upper layer portion of the drift layer 20. At that time, the Schottky trenches may be provided directly from the surface of the drift layer 20 instead of extending through the well regions 30.

Further, although in the first and second embodiments, the examples in which the first protection regions 31 and the second protection regions 32 are provided in the lower part of the trenches have been described, the first protection regions 31 and the second protections region 32 may not be provided in some cases. At this point, neither the first connection regions 33 nor the second connection regions 34 may be provided.

Furthermore, in the first and second embodiments, although aluminum (Al) is used as the p-type impurities, the p-type impurities may be boron (B) or gallium (Ga). The n-type impurities may be phosphorus (P) instead of nitrogen (N). In the MOSFETs described in the first and second embodiments, the gate insulating film is not necessarily an oxide film such as SiO₂ and may be an insulating film other than an oxide film, or a combination of an insulating film other than an oxide film and an oxide film. Further, although in the above-described embodiments, the crystal structure, the plane orientation of the main surface, the off-angle, the implantation conditions, and the like have been described with specific examples, the scope of application is not limited to these numerical ranges.

Further, in the above-described embodiment, the configuration in which an SBD is built-in in a so-called vertical MOSFET silicon carbide semiconductor device in which the drain electrode 85 is formed on the rear surface of the semiconductor substrate 10. However, a configuration is also adoptable in which an SBD is built-in in a so-called lateral MOSFET such as a RESURF (REduced SURface Field) type MOSFET in which the drain electrode 85 is formed on the surface of the drift layer 20. Further, the silicon carbide semiconductor device may be an insulated gate bipolar transistor (IGBT) with a built-in SBD. It can also be adoptable to a MOSFET and an IGBT having a super junction structure with a built-in SBD.

### Third Embodiment

In the present embodiment, the method of manufacturing the silicon carbide semiconductor device according to the above-described first and second embodiments is applied to a power conversion apparatus. Although the present disclosure is not limited to a method of manufacturing a specific power conversion apparatus, hereinafter, as a third embodiment, a case where the present disclosure is applied to a three-phase inverter will be described.

FIG. 24 is a block diagram illustrating a configuration a power conversion system to which a power conversion apparatus of the present embodiment is applied.

The power conversion system illustrated in FIG. 24 includes a power supply 100, a power conversion apparatus 200, and a load 300. The power supply 100 is a DC power supply and supplies DC power to the power conversion apparatus 200. The power supply 100 can be configured with various components, for example, the configuration thereof may include a DC system, a solar cell, and a storage battery, or include a rectifier circuit connected to an AC system or an AC/DC converter. Further, the power supply 100 may be configured by a DC/DC converter that converts the DC power output from the DC system into a predetermined power.

The power conversion apparatus 200 is a three-phase inverter connected between the power supply 100 and the load 300, which converts the DC power supplied from the power supply 100 into AC power and supplies AC power to the load 300. As illustrated in FIG. 30, the power conversion apparatus 200 includes a main conversion circuit 201 that converts DC power into AC power and outputs thereof, and a drive circuit 202 that outputs a drive signal for driving each switching element of the main conversion circuit 201, and a control circuit 203 that outputs a control signal for controlling the drive circuit 202 to the drive circuit 202.

The drive circuit 202 turns off each normally-off switching element by setting the voltage of the gate electrode and the voltage of the source electrode to the same potential.

The load 300 is a three-phase electric motor driven by AC power supplied from the power conversion apparatus 200. The load 300 is not limited to a specific application, and is an electric motor mounted on various electric devices. For example, the load 300 is used as an electric motor for a hybrid vehicle, an electric vehicle, a railroad vehicle, an elevator, or an air conditioning apparatus.

Hereinafter, the detailed description is made on the power conversion apparatus 200. The main conversion circuit 201 includes a switching element and a freewheeling diode (not illustrated), and by switching the switching element, the DC power supplied from the power supply 100 is converted into AC power and supplied to the load 300. There are various specific circuit configurations of the main conversion circuit 201, and the main conversion circuit 201 according to the present embodiment is a two-level three-phase full bridge circuit, and has six switching elements and six freewheeling diodes each of which is anti-parallel with the respective switching elements. For each switching element of the main conversion circuit 201, the silicon carbide semiconductor device manufactured by the method of manufacturing the silicon carbide semiconductor device according to any one of the first to third embodiments described above is applied. Each of the two switching elements connected in series among the six switching elements constitutes an upper and lower arm, and each upper and lower arm constitutes each phase (U-phase, V-phase, W-phase) of the full bridge circuit. Then, the output terminal of each upper and lower arm, that is, the three output terminals of the main conversion circuit 201 are connected to the load 300.

The drive circuit 202 generates a drive signal for driving the switching element of the main conversion circuit 201 and supplies the drive signal to the control electrode of the switching element of the main conversion circuit 201. Specifically, in response to the control signal from the control circuit 203 described later, a drive signal for turning on the switching element and a drive signal for turning off the switching element are output to the control electrode of each switching element. When the switching element is kept in the ON state, the drive signal is a voltage signal (ON signal) equal to or higher than a threshold voltage of the switching element, and when the switching element is kept in the OFF state, the drive signal is a voltage signal (OFF signal) equal to or lower than the threshold voltage of the switching element.

The control circuit 203 controls the switching elements of the main conversion circuit 201 so that the desired power is supplied to the load 300. Specifically, the control circuit 203 calculates the time (ON time) for each switching element of the main conversion circuit 201 to be in the ON state based on the power to be supplied to the load 300. For example, the main conversion circuit 201 is controlled by PWM control that modulates the ON time of the switching element according to the voltage to be output. Then, a control command (control signal) is output to the drive circuit 202 so that an ON signal is output to the switching element which is supposed to be turned on at each time point and an OFF signal is output to the switching element which is supposed to be turned off. The drive circuit 202 outputs an ON signal or an OFF signal as a drive signal to the control electrode of each switching element according to the control signal.

In the power conversion apparatus according to the present embodiment, the application of the silicon carbide semiconductor device manufactured by the method of manufacturing the silicon carbide semiconductor device according to the first and second embodiments to a switching element of the main conversion circuit 201, ensures a power conversion apparatus with low loss and improved reliability in high-speed switching.

Although in the present embodiment, the example where the present disclosure is applied to the two-level three-phase inverter has been described, the present disclosure is not limited there to, and can be applied to various power conversion apparatuses. Although in the present embodiment, a two-level power conversion apparatus is adopted, a three-level or multi-level power conversion apparatus may also be adoptable, and when power is supplied to a single-phase load, the present disclosure may also be adopted to a single-phase inverter. Further, when supplying power to a DC load or the like, the present disclosure is adoptable to the DC/DC converter or the AC/DC converter.

Further, the power conversion apparatus to which the resent disclosure is applied is not limited to the case where the above-mentioned load is an electric motor, the power conversion apparatus can be applied to the case where a load is a power supply device for an electric discharge machine, a laser machine, an induction heating cooker, or a contactless power supply system, further applied to the case where a load is a power conditioner for a solar power generation system and a power storage systems, for example.

### EXPLANATION OF REFERENCE SIGNS

10 SiC substrate, 20 drift layer, 30 well region, 31 first protection region, 32 second protection region, 33 first connection region, 34 second connection region, 35 connection region, 40 source region, 50 gate insulating film, 51 silicon oxide film, 55 interlayer insulating film, 60 gate electrode, 61 polycrystalline silicon film, 70 ohmic electrode, 71 rear surface ohmic electrode, 80 source electrode, 85 drain electrode, 90 resist mask, 100 power supply, 200 power conversion apparatus, 201 main conversion circuit, 202 drive circuit, 203 control circuit, 300 load.

1. A method of manufacturing a silicon carbide semiconductor device comprising the steps of:
forming a drift layer of a first conductive type on a silicon carbide semiconductor substrate;
forming a well region of a second conductive type on the drift layer;
forming a source region of the first conductive type in an upper layer portion of the well region;
forming a gate trench extending through the source region and the well region and reaching the drift layer;
forming a Schottky trench provided apart from the gate trench and reaching the drift layer;
forming a silicon oxide film in contact with the inner walls of the gate trench and the Schottky trench;
forming a polycrystalline silicon film inside the silicon oxide film in the gate trench and the Schottky trench;
forming a gate electrode in the gate trench by removing the polycrystalline silicon film outside the gate trench and the Schottky trench by etching back the polycrystalline silicon film;
forming an interlayer insulating film on the gate electrode in the gate trench;
removing, by wet etching, the polycrystalline silicon film in the Schottky trench after opening a hole in the interlayer insulating film;
after the step of removing the polycrystalline silicon film in the Schottky trench, forming an ohmic electrode on the source region;
after the step of forming the ohmic electrode, removing the silicon oxide film inside the Schottky trench and the silicon oxide film of the ohmic electrode on a side of the gate electrode; and
after the step of removing the silicon oxide film in the Schottky trench and the silicon oxide film of the ohmic electrode on the side of the gate electrode, forming a source electrode to be in a Schottky junction with the drift layer in the Schottky trench.

2. The method of manufacturing the silicon carbide semiconductor device according to claim 1, wherein
no interlayer insulating film is provided between the ohmic electrode and the Schottky trench being adjacent to each other.

3. The method of manufacturing the silicon carbide semiconductor device according to claim 1, further comprising the step of
forming protection regions of the second conductivity type in the drift layer at bottoms of the gate trench and the Schottky trench.

4. The method of manufacturing the silicon carbide semiconductor device according to claim 1, wherein
the ohmic electrode is composed of silicide.

5. The method of manufacturing the silicon carbide semiconductor device according to claim 1, wherein
the step of removing, by wet etching, the polycrystalline silicon film in the Schottky trench after opening a hole in the interlayer insulating film is performed in a state where the interlayer insulating film is formed on the gate electrode.

6. The method of manufacturing the silicon carbide semiconductor device according to claim 1, wherein
the step of removing the silicon oxide film in the Schottky trench is performed by wet etching using an etchant containing hydrofluoric acid.

7. The method of manufacturing the silicon carbide semiconductor device according to claim 1, wherein
the step of removing, by wet etching, the polycrystalline silicon film in the Schottky trench is performed by wet etching using an alkaline etchant.

8. The method of manufacturing the silicon carbide semiconductor device according to claim 1, wherein
the ohmic electrode is formed in the hole opened in the interlayer insulating film in a self-aligning manner.

9. A silicon carbide semiconductor device comprising:
a silicon carbide semiconductor substrate;
a drift layer of a first conductive type, formed on the silicon carbide semiconductor substrate;
a well region of a second conductive type formed on the drift layer;
a source region of the first conductivity type formed in an upper layer portion of the well region of the second conductive type;
a gate trench extending through the source region and the well region and reaching the drift layer;
a Schottky trench formed to reach the drift layer;
a gate electrode formed in the gate trench via gate insulating film;
an interlayer insulating film formed on the gate electrode and in the vicinity of an opening of the Schottky trench;
an ohmic electrode formed on the source region; and
a source electrode, which is formed on the interlayer insulating film, the ohmic electrode, and in the Schottky trench, is in direct contact with the source region on gate trench side of the ohmic electrode, and is in Schottky junction with the drift layer.

10. A power conversion apparatus, comprising :
a main conversion circuit including a silicon carbide semiconductor device manufactured by the method of manufacturing the silicon carbide semiconductor device according to claim 1 and configured to convert and output power to be input;
a drive circuit configured to cause an off operation by setting a voltage of the gate electrode of the silicon carbide semiconductor device to be the same as a voltage of the source electrode and output a drive signal for driving the silicon carbide semiconductor device to the silicon carbide semiconductor device; and
a control circuit configured to output a control signal for controlling the drive circuit to the drive circuit.

11. A power conversion apparatus comprising:
a main conversion circuit including a silicon carbide semiconductor device according to claim 9 and configured to convert and output power to be input;
a drive circuit configured to cause an off operation by setting a voltage of the gate electrode of the silicon carbide semiconductor device to be the same as a voltage of the source electrode and output a drive signal for driving the silicon carbide semiconductor device to the silicon carbide semiconductor device; and
a control circuit configured to output a control signal for controlling the drive circuit to the drive circuit.
